(19) United States
(12) Patent Application Publication
(10) Pub. No.: US 2013/0322186 A1
(43) Pub. Date: Dec. 5, 2013

(54) SEMICONDUCTOR MEMORY APPARATUS

(71) Applicant: Sang Ho LEE, Icheon-si (KR)

(72) Inventor: Sang Ho LEE, Icheon-si (KR)

(73) Assignee: SK HYNIX INC., Icheon-si (KR)

(21) Appl. No.: 13/602,042

(22) Filed: Aug. 31, 2012

(30) Foreign Application Priority Data
May 30, 2012 (KR) 10-2012-0057331

(51) Int. Cl. G11C 8/08; G11C 5/14

(52) U.S. Cl. 365/189.09; 365/230.06

(57) ABSTRACT

A semiconductor memory apparatus includes a plurality of mats each having a plurality of memory cells coupled to intersections between a plurality of word lines and bit lines which are arranged to cross each other, wherein a word line boosting voltage or negative word line voltage is driven onto a word line, depending on whether the corresponding word line is selected or not, and the negative word line voltage driven to a mat including the selected word line has a lower level than the negative word line voltage driven to a mat which does not include the selected word line.

### CROSS-REFERENCES TO RELATED APPLICATION

The present application claims priority under 35 U.S.C. §119(a) to Korean application number 10-2012-0057331 filed on May 30, 2012 in the Korean Intellectual Property Office, which is incorporated by reference in its entirety.

### BACKGROUND

1. Technical Field

The present invention relates to a semiconductor apparatus, and more particularly, to semiconductor memory apparatus with internal voltage control capabilities.

2. Related Art

In general, a semiconductor memory apparatus includes a plurality of mats each having a plurality of memory cells connected to the respective intersections between a plurality of word lines and bit lines, which are arranged to cross each other. By independently controlling each of the mats, it is possible to efficiently access a plurality of memory cells.

FIG. 1 is a block diagram of a conventional semiconductor memory apparatus.

The semiconductor memory apparatus includes a first mat 3A and a second mat 3B. Each of the first and second mats 3A and 3B includes a plurality of memory cells CELL, and is configured to store data in the memory cells CELL. Each of the memory cells has a gate controlled by a word line WL. The first and second mats 3A and 3B are connected to sub word line drivers 1A and 1B, respectively, to control the word line WL. Furthermore, the first and second mats 3A and 3B are connected to bit line sense amplifiers 4A and 4B, respectively, to sense and amplify data loaded onto a bit line BL.

FIG. 2 is a circuit diagram of the first sub word line driver 1A illustrated in FIG. 1. It will be easily understood by those in the art that the second sub word line driver 1B is configured in a similar manner as the first sub word line driver 1A.

The first sub word line driver 1A includes a first PMOS transistor and first and second NMOS transistors N1 and N2. The first sub word line driver 1A uses a word line boosting voltage PX and a negative word line voltage VBBW as driving voltages, and drives the word line WL in response to a main word line enable signal MWLB and a sub word line enable signal PXB.

The main word line enable signal MWLB is a signal for selecting a main word line, and may include a plurality of signals corresponding to the number of main word lines. The word line boosting signal PX and the sub word line enable signal PXB are signals for selecting a sub word line, and each may include a plurality of signals corresponding to the number of sub word lines allocated to a corresponding main word line. The sub word line enable signal PXB may be generated by inverting the level of the word line boosting voltage PX, and is a signal activated to a low level.

For example, suppose that any one of a plurality of word lines included in the first mat 3A is selected. Referring to FIG. 3, different voltages are driven to a selected word line WL1 and to an unselected word line WL2 of the first mat 3A. The word line boosting voltage PX is applied to the selected word line WL1 and the negative word line voltage VBBW is applied to the unselected word line WL2 by the sub word line driver 1A. After the word line WL1 is selected, the first bit line sense amplifier 4A connected to a bit line BL is enabled to load a core voltage VCORE or ground voltage VSS into a bit line pair BL/BLB having been precharged to a precharge voltage VBLP.

On the other hand, referring to 3B illustrating an operation waveform of the second mat 3B where no word line is selected, the word line WL and the bit line pair BL/BLB maintain the negative word line voltage VBBW and the precharge voltage VBLP, respectively. In general, the precharge voltage VBLP has a level half of the core voltage VCORE.

When an active operation is performed, a leakage current may occur in a memory cell transistor connected to the unselected word line, due to a voltage difference between source and drain terminals thereof. As described above, a maximum voltage difference between a data voltage and a bit line voltage, which are respectively connected to the source and drain terminals of the memory cell transistor included in the second mat 3B where no word line is selected, corresponds to VCORE/2, but a maximum voltage difference between a data voltage and a bit line voltage, which are respectively connected to source and drain terminals of a memory cell transistor connected to the unselected word line of the first mat 3A, may correspond to VCORE. Therefore, as a relatively high drain-source voltage level is applied to the memory cell transistor connected to the unselected word line of the first mat 3A, a larger data loss may occur in the memory cell transistor. This may degrade the entire refresh characteristic of the semiconductor memory apparatus.

### SUMMARY

In an embodiment of the present invention, a semiconductor memory apparatus includes a plurality of mats, each having a plurality of memory cells coupled to intersections between a plurality of word lines and bit lines which are arranged to cross each other, wherein a word line boosting voltage or negative word line voltage is driven onto a word line, depending on whether the corresponding word line is selected or not, and the negative word line voltage driven onto a mat including the selected word line has a lower level than the negative word line voltage driven to a mat which does not include the selected word line.

In an embodiment of the present invention, a semiconductor memory apparatus includes a first voltage generator configured to generate a first negative voltage, a second voltage generator configured to generate a second negative voltage having a lower level than the first negative voltage, a selector configured to output any one of the first or second negative voltages as a negative word line voltage in response to a mat select signal, and a sub word line driver configured to drive the word line boosting voltage or the negative word line voltage onto a word line in response to whether the corresponding word line is selected or not.

In an embodiment of the present invention, a semiconductor memory apparatus includes a first voltage generator configured to generate a first negative voltage, a second voltage generator configured to generate a second negative voltage having a lower level than the first negative voltage, a selector configured to output any one of the first or second negative voltages as a negative word line voltage in response to a mat select signal, a sub word line driver configured to use the word line boosting voltage and the negative word line voltage as driving voltages, and the capability to drive a word line in response to a main word line enable signal and a sub word line enable signal.

### BRIEF DESCRIPTION OF THE DRAWINGS

Features, aspects, and embodiments are described in conjunction with the attached drawings, in which:

FIG. 1 is a block diagram of a conventional semiconductor memory apparatus,

FIG. 2 is a circuit diagram of a first sub word line driver illustrated in FIG. 1,

FIG. 3A is an operation waveform diagram of a selected mat of FIG. 1,

FIG. 3B is an operation waveform diagram of an unselected mat of FIG. 1,

FIG. 4 is a block diagram of a semiconductor memory apparatus according to an embodiment of the present invention, and

FIG. 5 is a circuit diagram of a semiconductor memory apparatus according to an embodiment of the present invention.

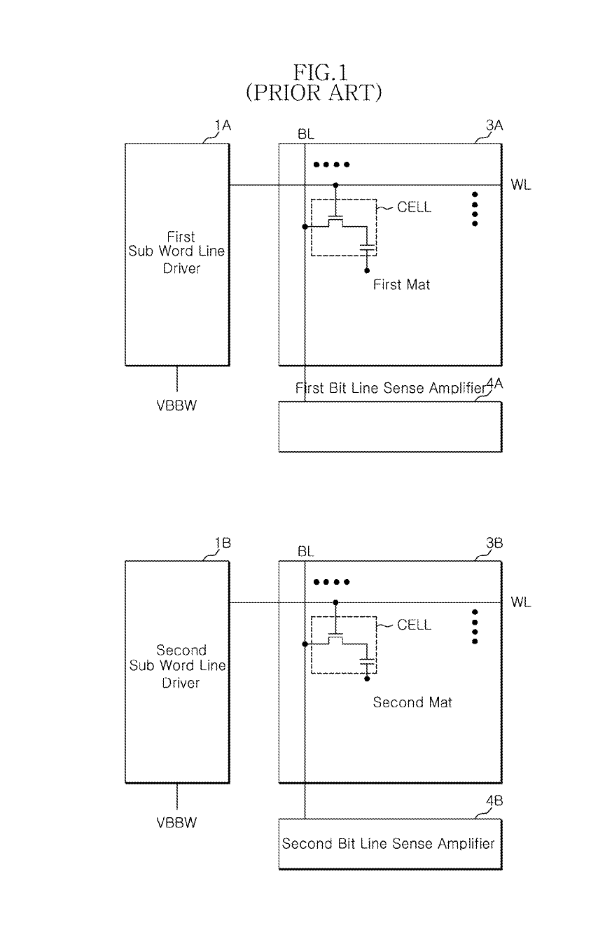

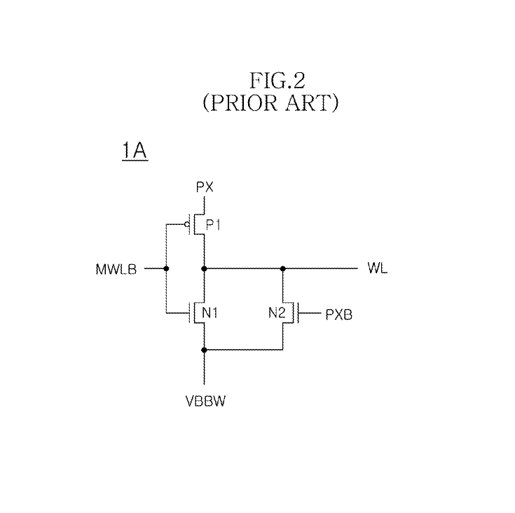

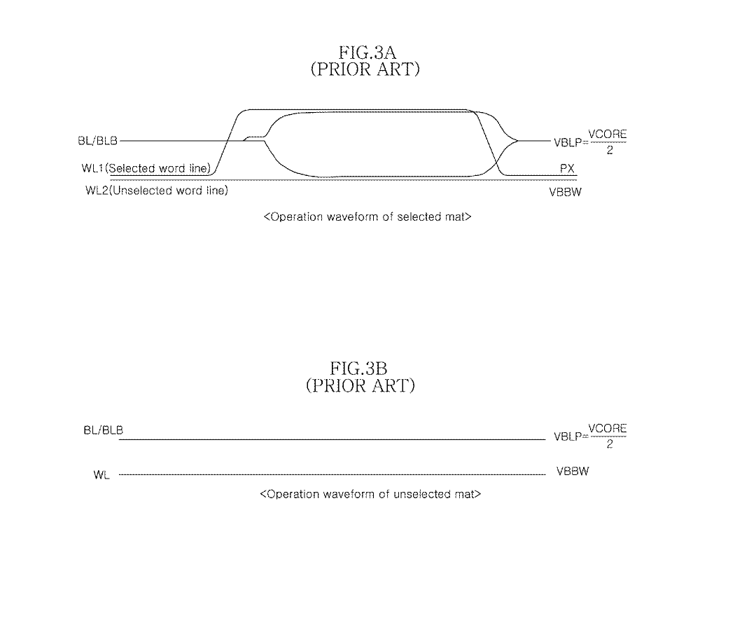

### DETAILED DESCRIPTION

Hereinafter, a semiconductor memory apparatus according to the present invention will be described below with reference to the accompanying drawings through various embodiments.

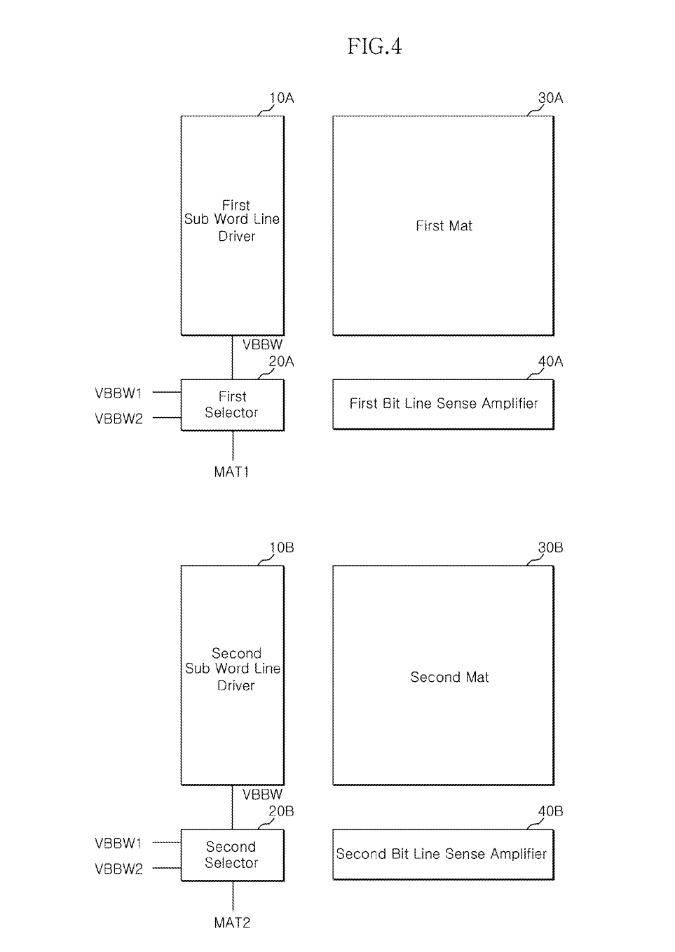

FIG. 4 is a block diagram of a semiconductor memory apparatus according to an embodiment of the present invention.

The semiconductor memory apparatus illustrated in FIG. 4 includes a first mat 30A and a second mat 30B. Each of the mats 30A and 30B includes a plurality of memory cells connected to the respective intersections between a plurality of word lines and bit lines, which are arranged to cross each other, and is configured to store data in the memory cells. Each of the memory cells has a gate controlled by a word line. The mats 30A and 30B are connected to sub word line drivers 10A and 10B, respectively, to drive a voltage to the word line. Furthermore, the mats 30A and 30B are connected to bit line sense amplifiers 40A and 40B, respectively, to sense and amplify data loaded onto a bit line. The configurations and operations of the mats 30A and 30B, the sub word line drivers 10A and 10B, and the bit line sense amplifiers 40A and 40B are similar to those of the above-described conventional memory apparatus.

The semiconductor memory apparatus according to an embodiment of the present invention further includes selectors 20A and 20B configured to receive two negative voltages VBBW1 and VBBW2 having different levels, and provide any one of the two negative voltages VBBW1 and VBBW2 as a negative word line voltage VBBW to the sub word line drivers 10A and 10B, depending on whether the mats are selected or not.

For example, suppose that a first negative voltage VBBW1 and a second negative voltage VBBW2 having a lower level than the first negative voltage VBBW1 are supplied. When the mats are not selected, the selectors 20A and 20B output the first negative voltage VBBW1 as the negative word line voltage VBBW, and when the mats are selected by mat select signals MAT1 and MAT2, the selectors 20A and 20B output the second negative voltage VBBW2 as the negative word line voltage VBBW.

Therefore, during an active operation, the negative word line voltage VBBW having the level of the first negative voltage VBBW1 is applied to a gate terminal of a memory cell transistor included in a mat where no word line is selected, and the negative word line voltage VBBW having the level of the second negative voltage VBBW2 is applied to a gate terminal of a memory cell transistor included in a mat including a selected word line. As the negative word line voltage VBBW distinguished into two levels is selectively supplied to the word line depending on whether the corresponding mat is enabled or not, a gate voltage having a relatively low level may be applied to a memory cell transistor to which a drain-source voltage having a relatively high level is applied. Accordingly, it is possible to improve the operation characteristic of the memory cell transistor having a relatively low leakage current characteristic.

The semiconductor memory apparatus may internally generate the first negative voltage VBBW1 and the second negative voltage VBBW2 having a lower level than the first negative voltage VBBW1, and receive the generated voltages. The first and second negative voltages VBBW1 and VBBW2 may be generated by a voltage pumping method. This is a general technique, and thus the detailed descriptions thereof are omitted herein.

Hereafter, the detailed operations of the semiconductor memory apparatus illustrated in FIG. 4 during an active operation will be described.

Suppose that, during the active operation, the first mat 30A is selected by the first mat select signal MAT1 and a specific word line included in the first mat 30A is enabled.

In this case, the first selector 20A may output the second negative voltage VBBW2 as the negative word line voltage VBBW in response to the activated first mat select signal MAT1. The first sub word line driver 10A includes a plurality of drivers configured to drive the respective word lines. Each of the drivers drives a word line boosting voltage (not illustrated) to a selected word line, and drives the negative word line voltage VBBW having the level of the second negative voltage VBBW2 to an unselected word line.

On the other hand, the second selector 20B may output the first negative voltage VBBW1 as the negative word line voltage VBBW in response to the deactivated second mat select signal MAT2. The second sub word line driver 10B includes a plurality of drivers configured to drive the respective word lines, and each of the drivers drives the negative word line voltage VBBW to the corresponding word line.

Therefore, according to the internal control of the semiconductor memory apparatus, a voltage having a lower level than the voltage applied to the word line of the unselected second mat 30B may be driven to the unselected word line of the selected first mat 30A.

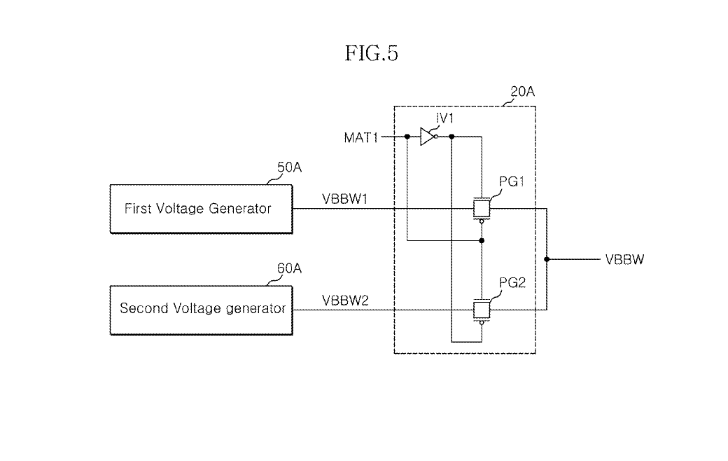

FIG. 5 illustrates a semiconductor memory apparatus, including a circuit diagram of the first selector 20A according to the embodiment of the present invention. It will be easily understood by those in the art that the second selector 20B is configured in a similar manner as the first selector 20A.

As described above, the semiconductor memory apparatus according to the embodiment of the present invention may further include a first voltage generator 50A configured to generate the first negative voltage VBBW1 and a second voltage generator 60A configured to generate the second negative voltage VBBW2. The respective mats 30A and 30B may share the first and second negative voltages VBBW1 and VBBW2 generated by the first and second voltage generators 50A and 60A.

The first selector 20A may include a first inverter IV1 and first and second pass gates PG1 and PG2.

The first inverter IV1 is configured to receive the first mat select signal MAT1 and output the inverted received first mat select signal MAT1.

The first pass gate PG1 is configured to output the first negative voltage VBBW1 as the negative word line voltage VBBW in response to the first mat select signal MAT1 and the inverted first mat select signal MAT1.

The second pass gate PG2 is configured to output the second negative voltage VBBW2 as the negative word line voltage VBBW in response to the first mat select signal MAT1 and the inverted first mat select signal MAT1.

When the deactivated first mat select signal MAT1 is applied, the first negative voltage VBBW1 is outputted as the negative word line voltage VBBW, and when the activated first mat select signal MAT1 is applied, the second negative voltage VBBW2 is outputted as the negative word line voltage VBBW.

The semiconductor memory apparatus according to the embodiment of the present invention divides the negative word line voltage provided to the selected mat and the negative word line voltage provided to the unselected mat, thereby preventing a data loss caused by leakage current which may occur in the memory cell transistor. Accordingly, it is possible to improve the refresh operation characteristic of the semiconductor memory apparatus.

While certain embodiments have been described above, it will be understood to those skilled in the art that the embodiments described are by way of example only. Accordingly, the semiconductor memory apparatus described herein should not be limited based on the described embodiments. Rather, the semiconductor memory apparatus described herein should only be limited in light of the claims that follow when taken in conjunction with the above description and accompanying drawings.

What is claimed is:

1. A semiconductor memory apparatus comprising a plurality of mats each having a plurality of memory cells coupled to intersections between a plurality of word lines and bit lines which are arranged to cross each other,
wherein a word line boosting voltage or negative word line voltage is driven onto a word line, depending on whether the corresponding word line is selected or not, and
wherein the negative word line voltage driven to a mat including the selected word line has a lower level than the negative word line voltage driven to a mat which does not include the selected word line.

2. The semiconductor memory apparatus according to claim 1, wherein, when the corresponding word line is selected, the word line boosting voltage is driven onto the word line, and
wherein, when the corresponding word line is not selected, the negative word line voltage is driven onto the word line.

3. A semiconductor memory apparatus comprising:
a first voltage generator configured to generate a first negative voltage;
a second voltage generator configured to generate a second negative voltage having a lower level than the first negative voltage;
a selector configured to output any one of the first or second negative voltages as a negative word line voltage in response to a mat select signal; and
a sub word line driver configured to drive the word line boosting voltage or the negative word line voltage onto a word line in response to whether the corresponding word line is selected or not.

4. The semiconductor memory apparatus according to claim 3, wherein the selector outputs the first negative voltage as the negative word line voltage when the deactivated mat select signal is applied, and outputs the second negative voltage as the negative word line voltage when the activated mat select signal is applied.

5. The semiconductor memory apparatus according to claim 4, wherein the selector comprises:
a first pass gate configured to output the first negative voltage as the negative word line voltage in response to the deactivated mat select signal; and
a second pass gate configured to output the second negative voltage as the negative word line voltage in response to the activated mat select signal.

6. The semiconductor memory apparatus according to claim 3, wherein the sub word line driver drives the word line boosting voltage onto the word line when the corresponding word line is selected, and drives the negative word line voltage onto the word line when the corresponding word line is not selected.

7. A semiconductor memory apparatus comprising:
a first voltage generator configured to generate a first negative voltage;
a second voltage generator configured to generate a second negative voltage having a lower level than the first negative voltage;
a selector configured to output any one of the first and second negative voltages as a negative word line voltage in response to a mat select signal; and
a sub word line driver configured to drive the word line boosting voltage or the negative word line voltage onto a word line in response to a main word line enable signal and a sub word line enable signal.

8. The semiconductor memory apparatus according to claim 7, wherein the selector outputs the first negative voltage as the negative word line voltage when the deactivated mat select signal is applied, and outputs the second negative voltage as the negative word line voltage when the activated mat select signal is applied.

9. The semiconductor memory apparatus according to claim 8, wherein the selector comprises:
a first pass gate configured to output the first negative voltage as the negative word line voltage in response to the deactivated mat select signal; and
a second pass gate configured to output the second negative voltage as the negative word line voltage in response to the activated mat select signal.

10. The semiconductor memory apparatus according to claim 7, wherein the sub word line driver drives the word line boosting voltage onto the word line when both of the main word line enable signal and the sub word line enable signal are activated, and drives the negative word line voltage to the word line in other cases.
